(19) United States
(12) Patent Application Publication
(10) Pub. No.: US 2026/0371990 A1
(43) Pub. Date: Nov. 19, 2026

(54) NONCONCENTRIC LAMP POSITIONING FOR IMPROVED THERMAL UNIFORMITY

(71) Applicant: Applied Materials, Inc., Santa Clara, CA (US)

(72) Inventors: Yen Lin LEOW, Santa Clara, CA (US); Aniketnitin PATIL, San Jose, CA (US); Hyeon Geu KIM, Santa Clara, CA (US)

(21) Appl. No.: 19/211,572

(22) Filed: May 19, 2025

(51) Int. Cl. H10P 72/00; C23C 16/458; H10P 72/50

(52) U.S. Cl. CPC H10P 72/0436; H10P 72/50; C23C 16/4584; C23C 16/4586

(57) ABSTRACT

A process chamber includes a chamber body having a processing volume. The substrate support is disposed in the processing volume, and the substrate support has a center and an axis of rotation. A lamp assembly faces the substrate support and has an arrangement of lamps, wherein a center of the arrangement of lamps is offset from the center of the substrate support, the axis of rotation, or both.

### BACKGROUND

### Field

Embodiments of the present disclosure generally relate to substrate processing equipment. More specifically, embodiments disclosed herein relate to arrangements of lamps for heating of semiconductor substrates.

### Description of the Related Art

Various processes are used to form electronic devices on semiconductor substrates. Such processes include chemical vapor depositions, plasma enhanced chemical vapor depositions, atomic layer depositions, and epitaxy. These processes are performed in process chambers, and temperature control across the surface of the semiconductor substrate disposed within the process chambers facilitates uniform and consistent results during processing.

Lamps are often used to heat the semiconductor substrates during processing. The lamps are often arranged radially relative to the center of the lamp. For example, a plurality of vertical lamps having a bulb extending towards the substrate can be arranged along various radii from a center of the lamp assembly. While these arrangements can provide adequate temperature control of radial locations on the substrates being processed, the temperature control around the different angular locations of the substrate still suffers from non-uniformities. Other arrangements, such as a honeycomb arrangement having hundreds or even thousands of lamps can provide improved temperature control, but having hundreds or thousands of lamps is not a cost-effective solution.

There is a need, therefore, for an improved arrangement of heating lamps in semiconductor process chambers.

### SUMMARY

In one embodiment, a process chamber includes a chamber body having a processing volume. The substrate support is disposed in the processing volume, and the substrate support has a center and an axis of rotation. A lamp assembly faces the substrate support and has an arrangement of lamps, wherein a center of the arrangement of lamps is offset from the center of the substrate support, the axis of rotation, or both.

In some embodiments, a method of processing a substrate in a process chamber includes positioning the substrate on a substrate support of the process chamber. The method also includes heating the substrate using a lamp assembly facing the substrate support. The lamp assembly has an arrangement of lamps, wherein a center of the arrangement of lamps is offset from a center of the substrate support. The method further includes rotating the substrate support while heating the substrate.

In some embodiments, a process chamber includes a chamber body having a processing volume. The substrate support is disposed in the processing volume, and the substrate support is configured to support the substrate in an offset alignment with a center of the substrate support. The process chamber also includes a lamp assembly facing the substrate support and having an arrangement of lamps.

In some embodiments, a process chamber includes a chamber body having a processing volume. The process chamber also includes a substrate support disposed in the processing volume and a lamp assembly facing the substrate support. The lamp assembly includes an arrangement of lamps defined by a center, wherein the center of the arrangement of lamps is offset from a center of the substrate support.

In some embodiments, a process chamber includes a chamber body having a processing volume. The process chamber also includes a substrate support disposed in the processing volume and a lamp assembly facing the substrate support. The lamp assembly includes a lamp arrangement having a plurality of rings of lamps defined by a center. The center of the lamp arrangement coincides with a center of the substrate support. At least two rings of lamps are asymmetrically aligned with respect to each other.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber, according to some embodiments.

FIG. 2 is a top view of an exemplary lamp arrangement disposed over a substrate support, according to some embodiments.

FIG. 3 is a schematic view of heating zones of a lamp arrangement disposed over a substrate, according to some embodiments.

FIG. 4 is a schematic view of heating zones of a lamp arrangement of FIG. 3 during rotation of the substrate, according to some embodiments.

FIG. 5 is a top view of another exemplary lamp arrangement disposed over a substrate support, according to some embodiments.

FIG. 6 is a top view of another exemplary lamp arrangement disposed over a substrate support, according to some embodiments.

FIG. 7 is a top view of another exemplary lamp arrangement disposed over a substrate support, according to some embodiments.

FIG. 8 is a top view of another exemplary lamp arrangement disposed over a substrate support, according to some embodiments.

FIG. 9A illustrates another exemplary lamp arrangement disposed over a substrate support, according to some embodiments. FIG. 9B shows a position of the substrate support after a 180 degree rotation from FIG. 9A.

FIG. 10A illustrates another exemplary lamp arrangement disposed over a substrate support, according to some embodiments. FIG. 10B shows a position of the substrate support after a 180 degree rotation from FIG. 10A.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure include a process chamber having a lamp assembly facing the substrate support. The lamp assembly includes an arrangement of lamps defined by a center, wherein the center of the arrangement of lamps is offset from a center of the substrate support. The offset alignment provides additional heating zones when the substrate support is rotated. In this respect, the offset alignment provides more flexibility for controlling a temperature profile of the different areas of the substrate support during processing.

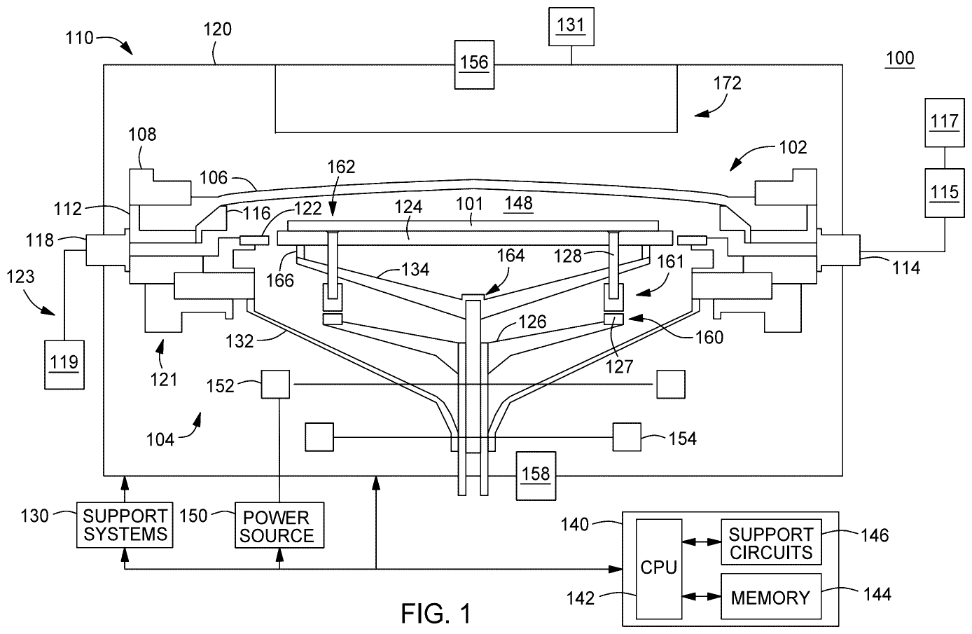

FIG. 1 depicts a schematic side view of a process chamber 100 in accordance with some embodiments of the present disclosure. In some embodiments, the process chamber 100 may be a suitably modified commercially available process chamber, such as any epitaxial deposition reactors available from Applied Materials, Inc. of Santa Clara, California, for example, any of the Centura® EPI line of process chambers or any suitable semiconductor process chamber that may use heating lamps as described herein. Other process chambers that use heating lamp assemblies may also benefit from the teachings provided herein.

In some embodiments, the process chamber 100 is an epitaxial deposition chamber. The process chamber 100 may generally comprise a chamber body 110, support systems 130, a controller 140, and a power source 150. The chamber body 110 generally includes an upper portion 102, a lower portion 104, and an enclosure 120. A vacuum system 123 may be coupled to the chamber body 110 to facilitate maintaining a desired pressure within the chamber body 110. In some embodiments, the vacuum system 123 may comprise a throttle valve (not shown) and vacuum pump 119 which are used to exhaust the chamber body 110. In some embodiments, the pressure inside the chamber body 110 may be regulated by adjusting the throttle valve and/or vacuum pump 119.

The upper portion 102 is disposed on the lower portion 104 and includes an upper dome 106, a clamp ring 108, a liner 116, a baseplate 112, an upper lamp module 172, and an upper pyrometer 156. The upper lamp module 172 is disposed above the upper dome 106. In some embodiments, the upper dome 106 has a dome-like form factor, however, lids having other form factors (e.g., flat or reverse curve lids) are also contemplated.

The lower portion 104 is coupled to an inlet port 114 and an exhaust port 118 and comprises a baseplate assembly 121, a lower dome 132, a substrate support 124, a pre-heat ring 122, a substrate lift assembly 160, a substrate support assembly 164, a lower heating lamp assembly 152, a lower reflector assembly 154 and a lower pyrometer 158. The upper dome 106 and the lower dome 132 are coupled to the chamber body 110 to define a processing volume 148 of the process chamber 100. The substrate support 124 is disposed in the processing volume 148 to support a substrate 101. The substrate support 124 is rotatable, and may be rotated by a rotation assembly (not shown), such as a magnetic rotation assembly. In some embodiments, the substrate 101 may be a semiconductor wafer, such as a 150 mm, 200 mm, 300 mm, 450 mm wafer, or the like, or any other type of substrate used in thin film fabrication processes. In some embodiments, the substrate 101 may be a patterned substrate.

Although the term “ring” is used to describe certain components of the process chamber 100, such as the pre-heat ring 122, the shape of these components need not be circular and may include any shape, including but not limited to polygons such as rectangles, hexagon or octagon, ovals, and the like. In some embodiments, a gas supply 117 may provide one or more process gases to the process chamber 100 via the inlet port 114. In such embodiments, a valve or mass flow controller 115 may be coupled to the gas supply 117 to control a flow of process gases from the gas supply 117. The upper dome 106, the clamp ring 108, and the lower dome 132 are formed from quartz; however, other IR-transparent and process compatible materials may also be used to form these components.

During processing, the substrate 101 is disposed on the substrate support 124. One or more heating lamp assemblies (e.g., heating lamp assembly 207 described below, lower heating lamp assembly 152) comprising a plurality of heating lamps, which are sources of infrared (IR) radiation (e.g., heat), are used to generate a pre-determined temperature distribution across the substrate 101. The one or more heating lamp assemblies receive power from the power source 150.

The substrate support assembly 164 generally includes a support bracket 134 having a plurality of support pins 166 coupled to the substrate support 124. The substrate lift assembly 160 comprises a substrate lift shaft 126 and a plurality of lift pin modules 161 selectively resting on respective pads 127 of the substrate lift shaft 126. In some embodiments, a lift pin module 161 comprises an optional upper portion of a lift pin 128 that is movably disposed through a first opening 162 in the substrate support 124. In operation, the substrate lift shaft 126 is moved to engage the lift pins 128. When engaged, the lift pins 128 may raise the substrate 101 above the substrate support 124 or lower the substrate 101 onto the substrate support 124.

The support systems 130 include components used to execute and monitor pre-determined processes (e.g., growing epitaxial films) in the process chamber 100. Such components generally include various sub-systems (e.g., gas panel(s), gas distribution conduits, vacuum and exhaust sub-systems, and the like) and devices (e.g., power supplies, process control instruments, and the like) of the process chamber 100. These components are well known to those skilled in the art and are omitted from the drawings for clarity.

The controller 140 may be provided and coupled to the process chamber 100 for controlling the components of the process chamber 100. The controller 140 may be any suitable controller for controlling the operation of a substrate process chamber. The controller 140 generally comprises a Central Processing Unit (CPU) 142, a memory 144, and support circuits 146 and is coupled to and controls the process chamber 100, support systems 130, and the power source 150, directly (as shown in FIG. 1) or, alternatively, via computers (or controllers) associated with the process chamber and/or the support systems.

The CPU 142 may be any form of a general-purpose computer processor that can be used in an industrial setting. The support circuits 146 are coupled to the CPU 142 and may comprise cache, clock circuits, input/output subsystems, power supplies, and the like. Software routines may be stored in the memory 144 of the controller 140. The software routines, when executed by the CPU 142, transform the CPU 142 into a specific purpose computer (controller) 140. The software routines may also be stored and/or executed by a second controller (not shown) that is located remotely from the controller 140. Alternatively, or in combination, in some embodiments, for example where the process chamber 100 is part of a multi-chamber processing system, each process chamber of the multi-chamber processing system may have a respective controller for controlling portions of the inventive methods disclosed herein that may be performed in that particular process chamber. In such embodiments, the individual controllers may be configured similar to the controller 140 and may be coupled to the controller 140 to synchronize operation of the process chamber 100.

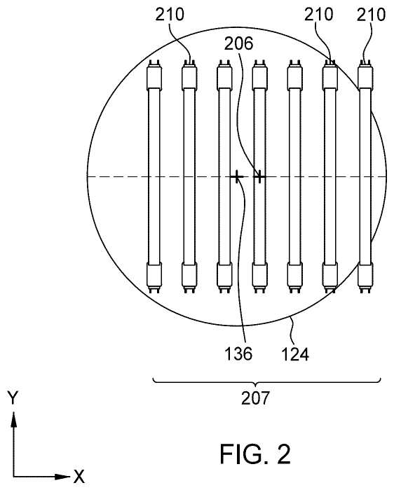

In some embodiments, the upper lamp module 172 includes an upper heating lamp assembly 278 having an arrangement 207 of lamps 210 (see FIG. 2) that project heat into the process volume 148 toward the substrate support 124. Exemplary lamps 210 include linear lamps, circular lamps, vertically oriented lamps, or other suitable heat sources. In some embodiments, the process chamber 100 may include one or more heating lamp assemblies, such as heating lamp assembly 278 and/or a heating lamp assembly 152, at the upper portion 102 and at the lower portion 104. The heating lamp assemblies 278, 152 may have reflective internal surfaces to increase the efficiency of power delivery to the processing surface of the substrate support 124. In some embodiments each lamp in the heating lamp assemblies 278, 152 may be disposed in a reflective tube to maximize power delivery from each lamp.

Interior surfaces of the upper lamp module 172 at the upper portion 102 of the chamber body 110 may be lined or coated with a reflective material if desired. The reflective material may be any reflective material capable of withstanding the environment of the heating lamp assembly 278. A cooling gas source 131 may be connected to the upper lamp module 172 through a gas conduit to maintain a temperature of the interior surfaces of the upper lamp module 172 at a desired level to avoid damage to the interior surfaces. The cooling gas may be an inert gas. A cooling gas source (not shown) may also be coupled to the lower heating lamp assembly 152 disposed below the substrate support 124. Reflective materials that may be used include gold, silver, or other metals, and dielectric reflectors.

FIG. 2 is top view of a heating lamp assembly 278 including an arrangement 207 of lamps 210 disposed over a substrate support 124 (or a substrate 101), according to some embodiments. FIG. 2 illustrates the arrangement 207 of lamps 210 having a center 206. In this example, the lamp arrangement 207 includes seven linear lamps 210. It is contemplated the lamp arrangement 207 may include any suitable number of lamps 210, such as four, six, eight, ten, fifteen, or more lamps 210. It is also contemplated the lamp arrangement 207 may include any suitable lamps arrangements, such as a circular lamp arrangement. In some examples, the lamp arrangement 207 generates a corresponding number of heating zones on the substrate support as the number of lamps 210 in the lamp arrangement 207.

In some embodiments, the lamps 210 in the arrangement 207 are disposed on a plane substantially parallel to the top surface of the substrate support 124. The linear lamps 210 can direct radiation towards substrates 101 located on the substrate support 124. Examples of suitable lamps to be used as the linear lamps 210 can include tungsten-halogen lamps, mercury vapor lamps, and carbon filament infrared emitters.

In some embodiments, the center 206 of the lamp arrangement 207 is the geometric center (e.g., the centroid) of the lamp arrangement 207. In this example, the center 206 of the lamp arrangement 207 is the intersection point of the midpoints of the length (i.e., Y-axis) and the width (i.e., X-axis) of the lamp arrangement 207. In another example, the centroid for a circular lamp arrangement is the mid-point of the diameter of the circular lamp arrangement. In FIG. 2, the lamps 210 are spaced apart at equal distances from each other. It can be seen that the lamp arrangement 207 is symmetrical in the X and Y directions. However, the lamps 210 can be spaced apart at different distances from each other.

In some embodiments, the arrangement 207 of lamps 210 has a non-concentric alignment with the substrate support 124. In one embodiment, the center 206 of the lamp arrangement 207 is offset from the center 136 of the substrate support 124, as shown in FIG. 2. In this example, the center 206 of the lamp arrangement 207 is offset along a horizontal direction (e.g., the X-axis) relative to the center 136 of the substrate support 124. However, the lamp arrangement 207 may be offset relative to the center 136 of the substrate support 124 along a vertical direction (e.g., Y-axis), a horizontal direction, or both. In some examples, the offset is less than or greater than the distance between two heating zones or two lamps 210. In some examples, the offset is from 0.05× to 0.95×, from 0.15× to 0.85×, from 0.05× to 0.6×, or from 0.4× to 0.95× the distance between two heating zones or two lamps 210. In some embodiments, the offset is such that a new position of a heating zone or lamp 210 is not at a previous position of another heating zone or lamp 210.

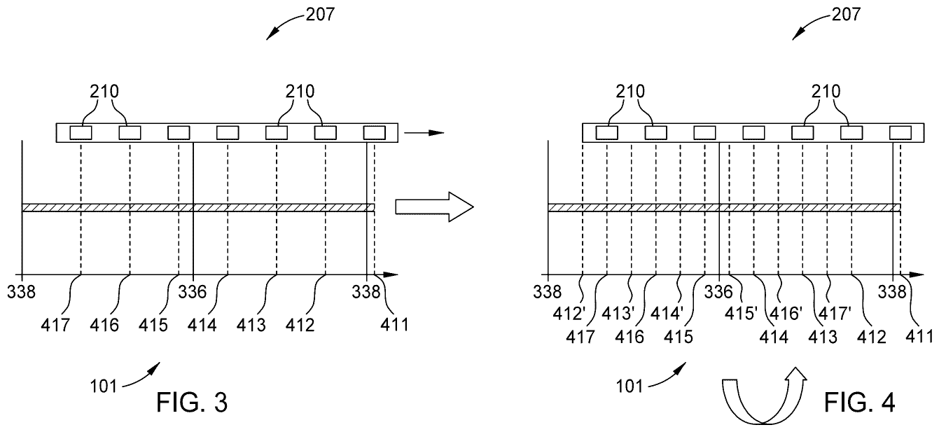

In some embodiments, the offset advantageously generates one or more additional heating zones on the substrate support 124 when the substrate support 124 is rotated. FIG. 3 is a schematic representation of heating zones of a lamp arrangement 207 (e.g., lamp arrangement 207 in FIG. 2) disposed over a substrate 101. The substrate 101 includes a central axis 336 and left and right edges 338. In this example, the lamp arrangement 207 has seven linear lamps 210 that are equally spaced apart. The seven lamps 210 initially present seven heating zones 411-417. As shown, the lamp arrangement 207 is offset from the central axis 336 of the substrate 101. In particular, the fourth (e.g., middle) heating zone 414 of the fourth lamp 210 is offset along the horizontal direction with respect to the central axis 336 of the substrate 101. The offset distance is less than the distance between the fourth heating zone 414 and the fifth heating zone 415.

Upon rotation of the substrate 101, additional heating zones are generated on the substrate 101. FIG. 4 shows the additional heating zones 412′ to 417′ that are generated when the substrate 101 is rotated. In this example, the initial heating zones 412 to 417 generate additional heating zones 412′ to 417′, respectively. In this respect, the total heating zones during rotation of the substrate 101 is represented by the formula (2n-1), where n is the number of lamps 210. The substrate 101 may be rotated for any suitable number of rotations. In some examples, the number of rotations completed at the end of the process, such as a deposition step, is an integer, e.g., full rotation increments. When the substrate rotation completed is an integer, the temperature symmetry around the center of the substrate is improved. In some embodiments, such as when a large number of rotations is to be completed for a process, the temperature symmetry around the center of the substrate is improved without completing the rotation as an integer.

The non-concentric alignment of the lamp arrangement 207 with respect to the substrate support 124 (or lamps 210) beneficially improves the uniformity of lamp heating on the substrate 101 while using the same number of lamps 210. The non-concentric alignment may also decrease the intensity of each heating zone, while increasing the number of heating zones. The non-concentric alignment may use fewer lamps to generate the same number of lamp heating zones. As a result, the lamp housing may be cooler due to a decrease in lamp density. The non-concentric alignment also allows the lamps targeting radii close to each other on the substrate to be placed in different quadrant, sectors, or semicircle of the substrate 101. Further still, the increased number of heating zones advantageously increases the number of thermal tuning zones available on the substrate 101, thereby providing more flexibility in the heating of the substrate 101. Because the number of lamps used can be decreased, the manufacturing of lamp arrangements and the reflectors may be easier and with less costs.

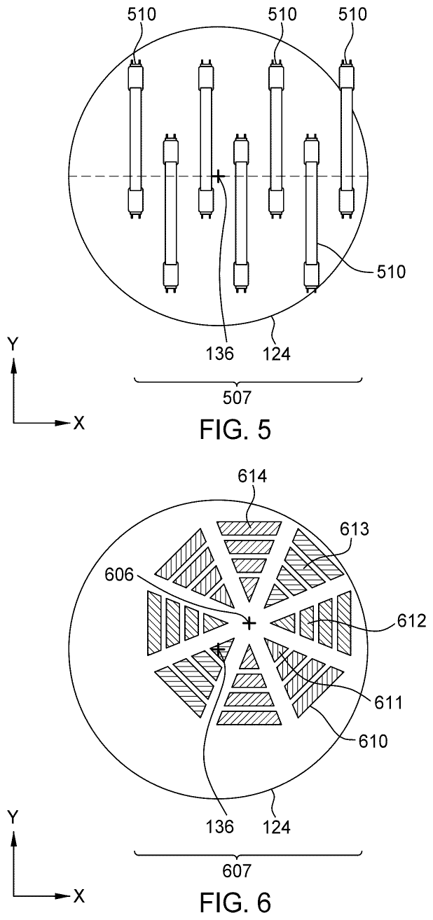

FIG. 5 illustrates another exemplary non-concentric lamp arrangement 507, according to some embodiments. As shown, the lamp arrangement 507 includes seven lamps 510 disposed over the substrate support 124. The lamps 510 are shorter than the lamps 210 shown in FIG. 2. Thus, because the number of heating zones are increased, the size of the lamps 510 may be smaller. All seven lamps 510 are offset in the horizontal direction relative to the center 136 of the substrate support 124. In addition, the lamps 510 are offset in the vertical direction relative to the center 136 of the substrate support 124. In particular, four lamps 510 are moved upward and three lamps 510 are move downward relative to the center 136. It can be seen that the lamp arrangement 507 is symmetrical in the horizontal direction.

FIG. 6 illustrates another exemplary non-concentric lamp arrangement 607, according to some embodiments. As shown, the lamp arrangement 607 includes a plurality of lamps 610 disposed in a ring-shaped arrangement having a center 606. In particular, the lamp arrangement 607 includes four concentric rings 611-614 of lamps 610 of different sizes. Each of the rings 611-614 is formed by eight lamps 610. The lamps 610 in the same ring 611-614 have the same size, and the lamps 610 in the different rings 611-614 have different sizes. For example, the outermost ring 614 has lamps 610 that are larger than the lamps 610 of the innermost ring 611. It can be seen that the lamp arrangement 607 is symmetrical in the X and Y directions. As shown, the center 606 of the lamp arrangement 607 is offset relative to the center 136 of the substrate support 124. In particular, the lamp arrangement 607 is offset along the horizontal direction and the vertical direction relative to the center 136 of the substrate support 124. While the offset is shown to the right and above the center 136, it is contemplated the offset can be to the left, below, or both relative to the center 136.

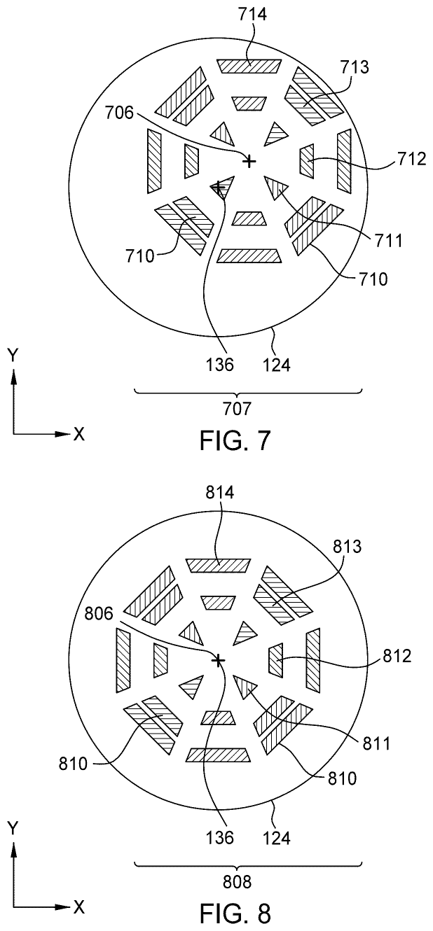

FIG. 7 illustrates another exemplary lamp arrangement 707 in a non-concentric alignment with substrate support 124, according to some embodiments. As shown, the lamp arrangement 707 includes a plurality of lamps 710 disposed in a ring-shaped arrangement having a center 706. In particular, the lamp arrangement 707 includes four concentric rings 711-714 of lamps 710 of different sizes. The lamps 710 in the same ring 711-714 have the same size, and the lamps 710 in the different rings 711-714 have different sizes. Similar to FIG. 6, the outermost ring 714 is formed by eight lamps 710. In contrast to FIG. 6, each of the three inner rings 711-713 are formed by four lamps 710, and therefore have fewer heating zones in each ring 711-713. Also, the lamps 710 in the three inner rings 711-713 alternate in position along the radial direction. As shown, the center 706 of the lamp arrangement 707 is offset relative to the center 136 of the substrate support 124. In particular, the lamp arrangement 707 is offset along the horizontal direction and the vertical direction relative to the center 136 of the substrate support 124. While the offset is shown to the right and above the center 136, it is contemplated the offset can be to the left, below, or both relative to the center 136. Although the lamp arrangement 707 has fewer lamps 710, the offset arrangement may provide for a sufficient number of heating zones to perform the substrate process.

FIG. 8 illustrates another exemplary lamp arrangement 808 disposed over the substrate support 124, according to some embodiments. As shown, the lamp arrangement 808 includes a plurality of lamps 810 disposed in a ring-shaped arrangement having a center 806. In this example, the center 806 of the lamp arrangement 808 is also the center 136 of the substrate support 124 (i.e., no offset). The lamp arrangement 808 includes four concentric rings 811-814 of lamps 810 of different sizes. The lamps 810 in the same ring 811-814 have the same size, and the lamps 810 in the different rings 811-814 have different sizes. Similar to FIG. 7, the outermost ring 814 is formed by eight lamps 810, and each of the three inner rings 811-813 is formed by four lamps 810. The lamps 810 in the three inner rings 811-813 alternate in position along the radial direction. In this respect, the rings 811-814 of the lamp arrangement 808 are considered to be asymmetrical. Upon rotation of the substrate support 124, the lamp arrangement 808 may advantageously provide for a sufficient number of heating zones to perform the substrate process even though the lamp arrangement 808 has fewer lamps 810.

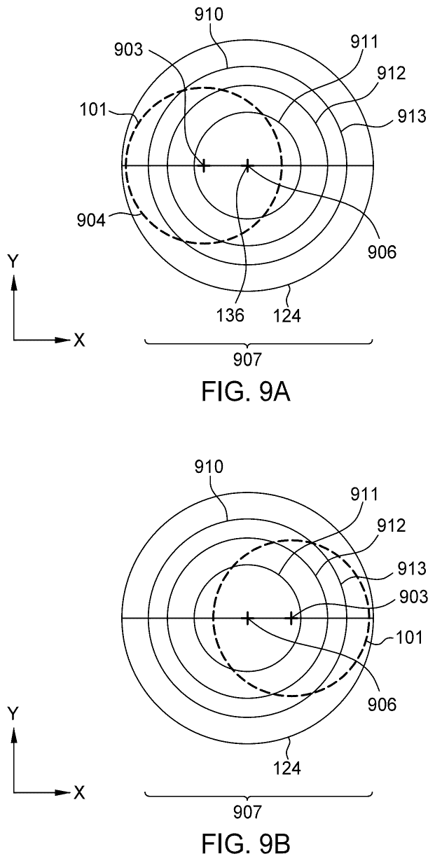

FIGS. 9A and 9B illustrate another exemplary lamp arrangement 907 disposed over the substrate support 124, according to some embodiments. In this example, the center 906 of the lamp arrangement 907 is also the center 136 of the substrate support 124 (i.e., no offset). As shown, the lamp arrangement 907 includes a plurality of lamps 910 disposed in a ring-shaped arrangement having a center 906. In particular, the lamp arrangement 907 includes three concentric rings 911-913 of lamps 910 of different sizes. For sake of clarity, the individual lamps 910 are not shown and are represented by the rings 911-913. The lamps 910 in the same ring 911-913 have the same size, and the lamps 910 in the different rings 911-913 have different sizes. In one example, each of the rings 911-913 is formed by eight lamps 910, similar to the lamp arrangement 607 of FIG. 6. The lamp arrangement 907 may be similar to the lamp arrangements 707, 808 in FIGS. 7 and 8, respectively, and include any suitable number of lamps or any suitable lamp sizes. It is contemplated that any suitable lamp arrangements or lamp shapes may be used, such as the linear lamps shown in FIG. 2.

In this example, the substrate 101 is positioned in an offset alignment with the substrate support 124 and the lamp arrangement 907. In particular, the center 903 of the substrate 101 is offset along a horizontal direction (e.g., the X-axis) relative to the center 906 of the lamp arrangement 907 and the center 136 of the substrate support 124. In some embodiments, the substrate 101 may be offset relative to the center 136 of the substrate support 124 along a vertical direction (e.g., Y-axis), the horizontal direction, or both. In some embodiments, the substrate 101 is placed in a susceptor pocket 904 in the substrate support 124 that is offset relative to the center 136 of the substrate support 124. In some embodiments, the center 906 of the lamp arrangement 907 is offset from the center 136 of the substrate support 124.

During processing, the substrate support 124 is rotated about its center 136. FIG. 9A shows the position of the substrate 101 relative to the lamp arrangement 907 at the beginning of the rotation. FIG. 9B shows the position of the substrate 101 relative to the lamp arrangement 907 after being rotated for 180 degrees. By positioning the substrate 101 in an offset alignment relative to the lamp arrangement 907, the lamp arrangement is less likely to cause hot spots on the substrate 101. In addition, the offset alignment of the substrate 101 may advantageously reduce the potential for substrate edge roll off or roll on.

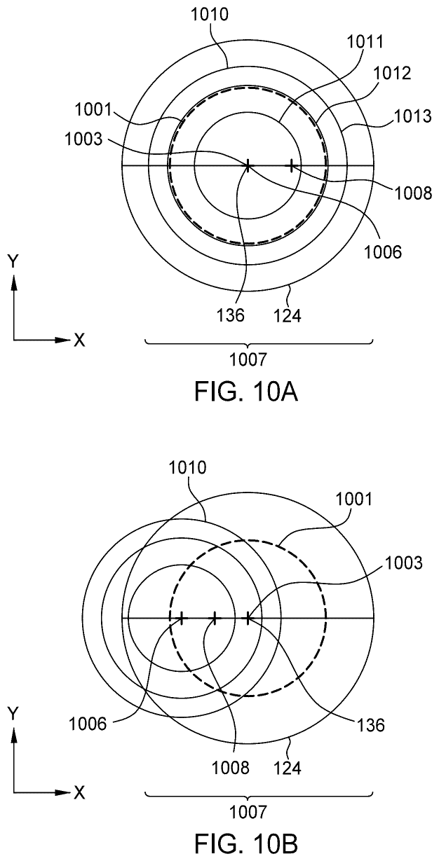

FIGS. 10A and 10B illustrate another exemplary lamp arrangement 1007 disposed over the substrate support 124, according to some embodiments. The center 1006 of the lamp arrangement 1007 is also the center 136 of the substrate support 124 (i.e., no offset). As shown, the lamp arrangement 1007 includes a plurality of lamps 1010 disposed in a ring-shaped arrangement having a center 1006. In particular, the lamp arrangement 1007 includes three concentric rings 1011-1013 of lamps 1010 of different sizes. For sake of clarity, the individual lamps 1010 are not shown and are represented by the rings 1011-1013. The lamps 1010 in the same ring 1011-1013 have the same size, and the lamps 1010 in the different rings 1011-1013 have different sizes. In one example, each of the rings 1013 is formed by eight lamps 1010, similar to the lamp arrangement 607 of FIG. 6. The lamp arrangement 1007 may be similar to the lamp arrangements 707, 808 in FIGS. 7 and 8, respectively, and include any suitable number of lamps or any suitable lamp sizes.

In this example, the lamp arrangement 1007, the substrate 1001, and the substrate support 124 are positioned in alignment. In particular, the center 1006 of the lamp arrangement 1007 is aligned with the center 136 of the substrate support 124 and the center 1003 of the substrate 1001. In this embodiment, the axis 1008 of rotation of the substrate support 124 is offset along a horizontal direction (e.g., the X-axis) relative to the center 136 of the substrate support 124 and the center 1006 of the lamp arrangement 1007. In some embodiments, the axis 1008 of rotation may be offset relative to the center 136 of the substrate support 124 along a vertical direction (e.g., Y-axis), the horizontal direction, or both. In some embodiments, the center 1006 of the lamp arrangement 1007 is offset from the center 136 of the substrate support 124. For example, with reference to FIG. 10A, the center 1006 of the lamp arrangement 1007 may be located between the center 136 of the substrate support 124 and the axis 1008 of rotation of the substrate support 124.

During processing, the substrate support 124 is rotated about its axis 1008 of rotation. FIG. 10A shows the position of the substrate 101 and the substrate support 124 relative to the lamp arrangement 1007 at the beginning of the rotation. It can be seen the center 1006 of the lamp arrangement 1007, the center 136 of the substrate support 124, and the center 1003 of the substrate 1001 are aligned. FIG. 10B shows the position of the substrate 101 and the substrate support 124 relative to the lamp arrangement 1007 after being rotated for 180 degrees. It can be seen that, after rotating 180 degrees, the center 1003 of the substrate 1001 and the center 136 of the substrate support 124 are now located to the right of the axis 1008 of rotation, and the center 1006 of the lamp arrangement 1007 remains to the left of the axis 1008 of rotation. By rotating the substrate support 124 about an axis 1008 of rotation that is offset from the center 136 of the substrate support 124 and the center 1006 of the lamp arrangement 1007, the lamps' 1010 heating zones will draft across the substrate 1001 in an arc, thereby advantageously resulting in heating of the substrate 1001 at different radii in different quadrants of the substrate 1001.

In some embodiments, one or more lamps in the lamp arrangement may be pulsed during rotation of the substrate support 124 to increase the number of heating zones or tune the heating zones. Referring back to FIG. 2, one or more lamps 210 of the lamp arrangement 207 can be pulsed on or off during rotation of the substrate support 124. In one example, the lamps 210 are pulsed on or off after every half of a rotation, or other suitable rotational periods, such as every quarter turn. In some examples, the lamps 210 are pulsed on or off after every completed rotation, or other suitable rotational periods, such as two or three full turns. In some embodiments, the lamps 210 are pulsed between two or more intensity levels. In some embodiments, one or more of the lamps 210 are pulsed at different cycles. For example, some of the lamps 210 are pulsed on and some of the lamps 210 are pulse off. In some embodiments, the lamps 210 may be pulsed in a sine wave pattern that corresponds with the rotational phase of the substrate 101. In some embodiments, the time period of pulsing the lamps 210 may be based on the rotational speed of the substrate support 124. For example, the pulse cycle may be longer if the substrate support 124 is rotating at a higher speed. In some embodiments, pulsing the lamps may allow a single lamp in the lamp arrangement to control heating at two or more radii, either discretely or continuously. In this manner, pulsing of the lamp arrangements 207, 507, 607, 808, 907, 1007 may provide more tunable heating zones for substrate processing.

With respect to the lamp arrangement of FIG. 2, it is believed that pulsing the lamps 210 in conjunction with the offset lamp arrangement 207 beneficially provides control of the heating of two or more radii in different quadrants of the substrate 101. With respect to the lamp arrangement of FIGS. 9A and 9B, it is believed that pulsing the lamps 910 in conjunction with rotating the offset substrate 101 beneficially provides control of heating at specific radii of the substrate 101 by synchronizing lamp output with the rotation phase. With respect to the lamp arrangement of FIGS. 10A and 10B, it is believed that pulsing the lamps 1010 in conjunction with rotating the substrate support 124 with respect to an offset axis 1008 beneficially provides the ability to reduce edge roll off and control of heating radii across four quadrants of the substrate 101.

Embodiments of the lamp arrangements disclosed herein can provide improved temperature control of different areas of the process chamber during processing. In some embodiments, the non-concentric alignment of the lamp arrangement relative to the substrate support or the substrate increases the number of heating zones in the process chamber, while using the same number of lamps. In some embodiments, the lamp arrangement may use fewer lamps to generate the same number of lamp heating zones. In some embodiments, the lamp arrangement may decrease the intensity of each heating zone, while increasing the number of heating zones. As a result, the lamp housing may be cooler due to a decrease in lamp density. In some embodiments, the temperature control of different areas of the process chamber may be further improved by pulsing one or more lamps in the lamp arrangement to increase the number of heating zones or tune the heating zones.

In some embodiments, the non-concentric alignment allows the lamps targeting radii close to each other on the substrate to be placed in different quadrant, sectors, or semicircle of the substrate. Further still, the increased number of heating zones advantageously increases the number of thermal tuning zones available on the substrate, thereby providing more flexibility in the heating of the substrate. Because the number of lamps used can be decreased, the manufacturing of lamp arrangements and the reflectors may be easier and with less costs.

In some embodiments, a process chamber includes a chamber body having a processing volume. The process chamber also includes a substrate support disposed in the processing volume and a lamp assembly facing the substrate support. The lamp assembly includes a lamp arrangement having a plurality of rings of lamps defined by a center. The center of the lamp arrangement coincides with a center of the substrate support. At least two rings of lamps are asymmetrically aligned with respect to each other.

In some embodiments, a first ring of lamps of the at least two rings of lamps has one or more lamps not in radial alignment with one or more lamps of a second ring of lamps of the at least two rings of lamps.

In some embodiments, the first ring and the second ring have a circular shape or a polygonal shape.

While the foregoing is directed to embodiments of the present disclosure, other and further embodiments of the disclosure may be devised without departing from the basic scope thereof, and the scope thereof is determined by the claims that follow.

1. A process chamber, comprising:
a chamber body having a processing volume;
a substrate support disposed in the processing volume, the substrate support having a center and an axis of rotation; and
a lamp assembly facing the substrate support and having an arrangement of lamps, wherein a center of the arrangement of lamps is offset from the center of the substrate support, the axis of rotation, or both.

2. The process chamber of claim 1, wherein the lamps generate a corresponding number of heating zones on the substrate support.

3. The process chamber of claim 2, wherein the number of heating zones increases upon rotation of the substrate support.

4. The process chamber of claim 3, wherein one or more of the lamps is pulsed on or off during rotation.

5. The process chamber of claim 1, wherein the offset is in a horizontal direction, a vertical direction, or both.

6. The process chamber of claim 1, wherein the arrangement of lamps is symmetrical or asymmetrical.

7. The process chamber of claim 1, wherein center of the arrangement of lamps is offset from the axis of rotation of the substrate support.

8. The process chamber of claim 1, wherein the offset is less than or more than a distance between two adjacent lamps in the arrangement.

9. The process chamber of claim 1, wherein the center and the axis of rotation of the substrate support are not aligned.

10. The process chamber of claim 1, wherein the arrangement of lamps has a ring shaped-arrangement or a linear arrangement.

11. The process chamber of claim 10, wherein the ring-shaped arrangement of lamps is one of a circular shape or a polygonal shape.

12. A method of processing a substrate in a process chamber, comprising:
positioning the substrate on a substrate support of the process chamber,
heating the substrate using a lamp assembly facing the substrate support, the lamp assembly having an arrangement of lamps, wherein a center of the arrangement of lamps is offset from a center of the substrate support; and
rotating the substrate support while heating the substrate.

13. The method of claim 12, wherein rotating the substrate support comprise rotating the substrate support in full rotation increments.

14. The method of claim 12, further comprising pulsing one or more lamps in the lamp arrangement on and off while rotating the substrate support.

15. The method of claim 12, further comprising changing an intensity of one or more lamps in the lamp arrangement while rotating the substrate support.

16. The method of claim 12, wherein the lamp arrangement generates a corresponding number of heating zones on the substrate support.

17. The method of claim 16, wherein the number of heating zones increases upon rotation of the substrate support.

18. A process chamber for processing a substrate, comprising:
a chamber body having a processing volume;
a substrate support disposed in the processing volume, the substrate support configured to support the substrate in an offset alignment with a center of the substrate support; and
a lamp assembly facing the substrate support and having an arrangement of lamps.

19. The process chamber of claim 18, wherein a center of the lamp assembly is aligned with the center of the substrate support.

20. The process chamber of claim 18, wherein the substrate support includes a pocket for supporting the substrate in the offset alignment.
